(19) United States
(12) Patent Application Publication
(10) Pub. No.: US 2025/0309012 A1
(43) Pub. Date: Oct. 2, 2025

(54) SEMICONDUCTOR PACKAGE

(71) Applicant: SAMSUNG ELECTRONICS CO., LTD., Suwon-si (KR)

(72) Inventor: Junghoon Kang, Suwon-si (KR)

(21) Appl. No.: 18/889,803

(22) Filed: Sep. 19, 2024

(30) Foreign Application Priority Data
Mar. 29, 2024 (KR) 10-2024-0043660

(51) Int. Cl. H01L 23/13; H01L 23/00; H01L 23/14; H01L 23/31; H01L 23/498; H01L 23/538; H01L 25/065

(52) U.S. Cl. CPC H01L 23/13; H01L 23/49811; H01L 23/538; H01L 24/24; H01L 25/0657; H01L 23/145; H01L 23/3107; H01L 24/32; H01L 24/33; H01L 24/73; H01L 2224/24105; H01L 2224/24146; H01L 2224/244; H01L 2224/32145; H01L 2224/32245; H01L 2224/33181; H01L 2224/73267

(57) ABSTRACT

An example semiconductor package includes a first encapsulation layer, a plurality of semiconductor dies stacked in a staircase structure on the first encapsulation layer, a second encapsulation layer that covers the plurality of semiconductor dies and the first encapsulation layer, a wiring layer on the second encapsulation layer, and a plurality of first vertical connectors that connect the semiconductor dies with the wiring layer. The first encapsulation layer includes a polymer layer and a metal layer between the polymer layer and the second encapsulation layer.

### CROSS-REFERENCE TO RELATED APPLICATION

This application claims priority under 35 U.S.C § 119 to Korean Patent Application No. 10-2024-0043660 filed on Mar. 29, 2024, in the Korean Intellectual Property Office, the disclosure of which is hereby incorporated by reference in its entirety.

### BACKGROUND

A semiconductor package is provided to implement an integrated circuit chip to be suitable for use in electronic products. A semiconductor package is typically configured such that a semiconductor chip is mounted on a printed circuit board and bonding wires or bumps are used to electrically connect the semiconductor chip to the printed circuit board. With the development of electronic industry, various studies have been conducted to improve reliability and durability of semiconductor packages.

### SUMMARY

The present disclosure relates to a semiconductor package with good marking visibility, a semiconductor package with improved accuracy of chip alignment, and a semiconductor package with increased thermal radiation efficiency.

In some implementations, a semiconductor package may comprise: a first encapsulation layer; a plurality of semiconductor dies offset stacked on the first encapsulation layer; a second encapsulation layer that covers the semiconductor dies and the first encapsulation layer; a wiring layer on the second encapsulation layer; and a plurality of first vertical connectors that connect the semiconductor dies to the wiring layer. The first encapsulation layer may include: a polymer layer; and a metal layer between the polymer layer and the second encapsulation layer.

In some implementations, a semiconductor package may comprise: a metal layer; a plurality of semiconductor dies offset stacked on the metal layer; a second encapsulation layer that covers the semiconductor dies and the metal layer; a wiring layer on the second encapsulation layer; a plurality of first vertical connectors that connect the semiconductor dies to the wiring layer; and a plurality of second vertical connectors that connect the metal layer to the wiring layer. The second vertical connectors may be horizontally spaced apart from the semiconductor dies.

In some implementations, a semiconductor package may comprise: a metal layer; a first semiconductor die offset stacked on the metal layer; a second encapsulation layer that covers the first semiconductor die and the metal layer; a wiring layer on the second encapsulation layer; and a plurality of first vertical connectors that connect the first semiconductor die to the wiring layer. The metal layer may include a first alignment key on a surface that faces the second encapsulation layer. The first alignment key may have a depressed shape. The second encapsulation layer may fill the first alignment key.

### BRIEF DESCRIPTION OF THE DRAWINGS

FIG. 1 illustrates a cross-sectional view showing an example of a semiconductor package.

FIG. 2A illustrates an example enlarged view showing section A of FIG. 1.

FIG. 2B illustrates an example enlarged view showing section A of FIG. 1.

FIG. 2C illustrates an example enlarged view corresponding to section A of FIG. 1.

FIGS. 3, 4, 5, 6, 7, 8, 9, and 10 illustrate cross-sectional views showing an example of a method of fabricating a semiconductor package.

FIG. 11 illustrates a cross-sectional view showing an example of a semiconductor package.

### DETAILED DESCRIPTION

Some implementations of the present disclosure will now be described in detail with reference to the accompanying drawings to aid in clearly explaining the present disclosure.

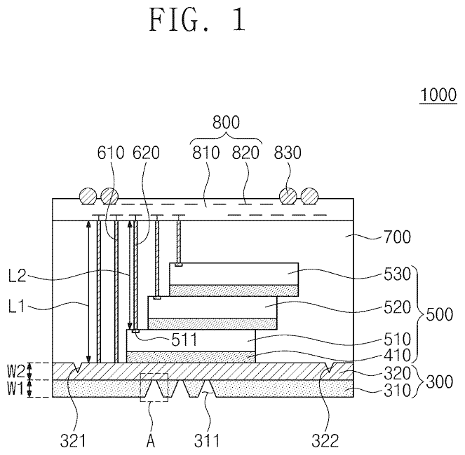

FIG. 1 illustrates a cross-sectional view showing an example of a semiconductor package.

Referring to FIG. 1, a semiconductor package 1000 may include a first encapsulation layer 300, a chip stack structure 500 that is offset stacked (for example, stacked in a staircase structure) on the first encapsulation layer 300, a second encapsulation layer 700 that covers the chip stack structure 500 and the first encapsulation layer 300, a wiring layer 800 on the second encapsulation layer 700, and first vertical connectors 620 that connect the chip stack structure 500 to the wiring layer 800.

The first encapsulation layer 300 may include a first material layer 310 and a second material layer 320 on the first material layer 310. The first material layer 310 and the second material layer 320 may include different materials from each other. The first material layer 310 may be, for example, a polymer layer. The first material layer 310 may include at least one selected from polypropylene, polyimide, polyvinyl alcohol, and polyvinylidene fluoride, but the present disclosure are not limited thereto. The second material layer 320 may be, for example, a metal layer. The second material layer 320 may include at least one selected from copper, aluminum, tungsten, and titanium, but the present disclosure are not limited thereto.

The first material layer 310 may have a thickness W1 of about 10 nm to about 10 μm. The second material layer 320 may have a thickness W2 of about 50 nm to about 50 μm. The thickness W1 of the first material layer 310 may be less than the thickness W2 of the second material layer 320.

The first encapsulation layer 300 may include a marking pattern 311 disposed on a surface parallel to another surface that faces the second encapsulation layer 700. The marking pattern 311 may include at least one opening.

The second material layer 320 may include a first alignment key 321 and a second alignment key 322 that are disposed on a surface that faces the second encapsulation layer 700. The first alignment key 321 and the second alignment key 322 may each independently have a depressed shape.

The second material layer 320 may be provided with second vertical connectors 610 on the surface that faces the second encapsulation layer 700. The second vertical connectors 610 may connect the second material layer 320 to the wiring layer 800. The second vertical connectors 610 may include, for example, metal. The second vertical connectors 610 may include at least one selected from copper, aluminum, tungsten, and titanium, but the present disclosure are not limited thereto. The second vertical connectors 610 may include a material the same as or different from that of the second material layer 320.

The second vertical connectors 610 may be horizontally spaced apart from the chip stack structure 500, for example, semiconductor dies 510, 520, and 530 which will be discussed below. The second vertical connectors 610 may be horizontally disposed between the first alignment key 321 and the second alignment key 322. A length L1 of the second vertical connectors 610 may be greater than a length L2 of the first vertical connectors 620.

The chip stack structure 500 may be disposed on the first encapsulation layer 300, for example, the second material layer 320. The chip stack structure 500 may include semiconductor dies 510, 520, and 530, a die adhesion layer 410 disposed on each of the semiconductor dies 510, 520, and 530, and contact pads 511 disposed on one surface of each of the semiconductor dies 510, 520, and 530.

The semiconductor dies 510, 520, and 530 may be offset stacked on the first encapsulation layer 300, for example, the second material layer 320. The semiconductor dies 510, 520, and 530 may each have integrated memory devices. The semiconductor dies 510, 520, and 530 may include a first semiconductor die 510, a second semiconductor die 520, and a third semiconductor die 530. Among the semiconductor dies 510, 520, and 530, the first semiconductor die 510 may be most adjacent to the second material layer 320. The third semiconductor die 530 may be disposed on the first semiconductor die 510. The second semiconductor die 520 may be interposed between the first semiconductor die 510 and the third semiconductor die 530.

Although FIG. 1 depicts three semiconductor dies, the number of semiconductor dies may be greater or less and is not limited to three.

The first semiconductor die 510 may be horizontally disposed between the first alignment key 321 and the second alignment key 322. The chip stack structure 500, for example, the semiconductor dies 510, 520, and 530 may be horizontally disposed between the first alignment key 321 and the second alignment key 322.

The semiconductor dies 510, 520, and 530 may each have one surface and another surface, and the one surface may be closer than the another surface to the wiring layer 800. The one surface of each of the semiconductor dies 510, 520, and 530 may be an active surface. The contact pads 511 may be included on the one surface of each of the semiconductor dies 510, 520, and 530. The contact pads 511 may include bonding terminals that are electrically and signally coupled to each of the semiconductor dies 510, 520, and 530. Each of the semiconductor dies 510, 520, and 530 may be connected to the wiring layer 800 through the contact pads 511 and the first vertical connectors 620.

The die adhesion layer 410 may be provided on the another surface of each of the semiconductor dies 510, 520, and 530. The die adhesion layer 410 may attach the first semiconductor die 510 and the second material layer 320 to each other. The die adhesion layer 410 may attach the first semiconductor die 510 and the second semiconductor die 520 to each other or the second semiconductor die 520 and the third semiconductor die 530 to each other.

The first vertical connectors 620 may connect each of the semiconductor dies 510, 520, and 530 to the wiring layer 800. The first vertical connectors 620 may include, for example, metal. The first vertical connectors 620 may include at least one selected from copper, aluminum, tungsten, and titanium, but the present disclosure are not limited thereto. The first vertical connectors 620 may include a material the same as or different from that of the second material layer 320. The material of the first vertical connectors 620 may be the same or different from that of the second vertical connectors 610. The first vertical connectors 620 may be horizontally disposed between the first alignment key 321 and the second alignment key 322.

The second encapsulation layer 700 may be disposed on the semiconductor dies 510, 520, and 530 and the first encapsulation layer 300. The second encapsulation layer 700 may cover the semiconductor dies 510, 520, and 530 and the first encapsulation layer 300. The second encapsulation layer 700 may cover a lateral surface of each of the first vertical connectors 620 and a lateral surface of each of the second vertical connectors 610. The second encapsulation layer 700 may be in contact with a top surface of the second material layer 320. The second encapsulation layer 700 may independently fill the first alignment key 321 and the second alignment key 322. The second encapsulation layer 700 may include, for example, an epoxy molding compound (EMC).

The wiring layer 800 may be disposed on the second encapsulation layer 700. The wiring layer 800 may be, for example, a redistribution layer. The wiring layer 800 may include an interconnection structure and/or a printed circuit board (PCB).

The wiring layer 800 may include a dielectric layer 810 and wiring patterns 820. The wiring patterns 820 may be disposed in the dielectric layer 810, and may be insulated from each other by the dielectric layer 810.

The dielectric layer 810 may include a photosensitive polymer. The photosensitive polymer may include, for example, at least one selected from photosensitive polyimide (PSPI), polybenzoxazole (PBO), phenolic polymers, and benzocyclobutene (BCB) polymers.

The wiring patterns 820 may include conductive patterns electrically and signally connected to the first vertical connectors 620 and the second vertical connectors 610. The wiring patterns 820 may include signal transfer lines and power transfer lines that are connected through the first vertical connectors 620 to the semiconductor dies 510, 520, and 530. The wiring patterns 820 may include thermal transfer lines or dummy lines connected through the second vertical connectors 610 to the second material layer 320.

External bonding terminals 830 may be disposed on the wiring layer 800. The external bonding terminals 830 may be disposed on and electrically connected to the wiring patterns 820. The external bonding terminals 830 may be shaped like a solder ball.

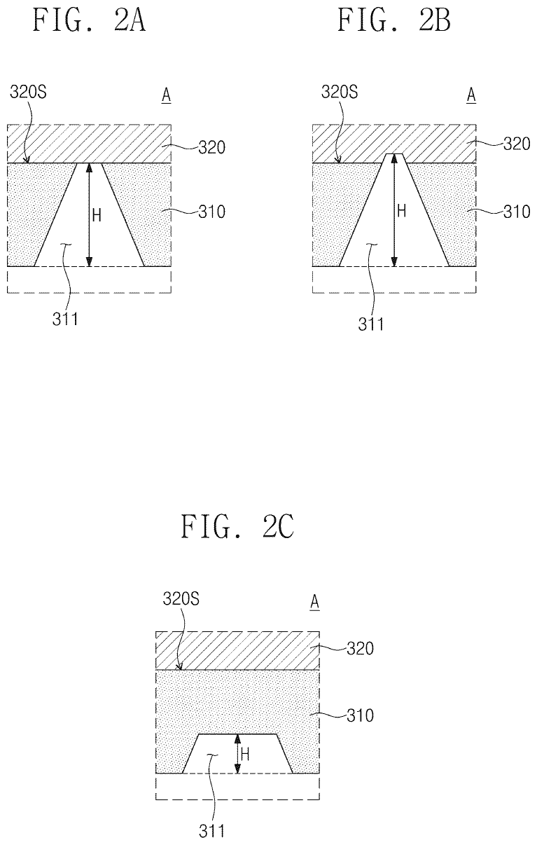

FIGS. 2A, 2B, and 2C illustrate example enlarged views showing section A of FIG. 1.

Referring to FIG. 2A, an opening of the marking pattern 311 may expose a bottom surface 320S of the second material layer 320. For example, the opening of the marking pattern 311 may have a depth H the same as the thickness W1 of the first material layer 310.

Referring to FIG. 2B, an opening of the marking pattern 311 may expose the second material layer 320. The exposed portion of the second material layer 320 may be located at a level higher than that of a bottom surface 320S of the second material layer 320. The opening of the marking pattern 311 may have a depth H greater than the thickness W1 of the first material layer 310.

Referring to FIG. 2C, an opening of the marking pattern 311 may not expose the second material layer 320. The opening of the marking pattern 311 may have a depth H less than the thickness W1 of the first material layer 310.

In a semiconductor package according to a comparative example, the first encapsulation layer 300 may include only one material layer. For example, the second material layer 320 may not be interposed between the first material layer 310 and the second encapsulation layer 700. In the semiconductor package according to a comparative example, the absence of the second material layer 320 may cause a reduction in visibility when the marking pattern 311 is formed, and this may induce unnecessary cost issues such as high-resolution equipment is required for inspection.

In contrast, in the semiconductor package 1000 according to the present disclosure, when the marking pattern 311 is formed under the presence of the second material layer 320, a difference in gray value between a portion where the marking pattern 311 is formed and a portion where the marking pattern 311 is not formed may become clearly evident, thereby improving visibility.

The visibility may be measured through the difference in gray value between a portion where the marking pattern 311 is formed and a portion where the marking pattern 311 is not formed. When exposed to light whose wavelength is 532 nm under the same condition where the thickness W1 of the first material layer 310 is 5 μm and the depth H of the marking pattern 311 is 3 μm, the gray value was compared between a comparative example in which the second material layer 320 is absent and an implementation in which the thickness W2 is 10 μm.

In the comparative example, the gray value was 197 in the case of the first material layer 310 without the marking pattern 311 and was 178 in the case of the first material layer 310 with the marking pattern 311, resulting in a gray value difference of 19. In contrast, in some implementations, the gray value was 223 in the case of the first material layer 310 without the marking pattern 311 and was 153 in the case of the first material layer 310 with the marking pattern 311, resulting in a gray value difference of 70. In this sense, it may be ascertained that the presence of the second material layer 320 significantly enhances the visibility of the marking pattern 311.

The semiconductor package according to the comparative example may not include any of the second material layer 320 and the second vertical connectors 610 of FIG. 1. The semiconductor package 1000 according to the present disclosure may include the second material layer 320 connected through the die adhesion layer 410 to the first semiconductor die 510 and may also include the second vertical connectors 610 directly connected to the second material layer 320. In the semiconductor package 1000 according to the present disclosure, heat generated from the semiconductor dies 510, 520, and 530 may be discharged to the wiring layer 800 through the first vertical connectors 620 and the second vertical connectors 610. As a result, the semiconductor package 1000 may improve in thermal radiation efficiency.

The semiconductor package according to the comparative example may not include any of the second material layer 320 and the chip-level alignment keys 321 and 322 of FIG. 1. The semiconductor package according to the comparative example may include wafer-level or panel-level alignment keys. In the semiconductor package 1000 according to the present disclosure, the chip-level alignment keys 321 and 322 may be disposed on the second material layer 320. In such a configuration, as each semiconductor chip includes alignment keys, the semiconductor package 1000 according to the present disclosure may have improved accuracy of alignment, compared to the semiconductor package of the comparative example.

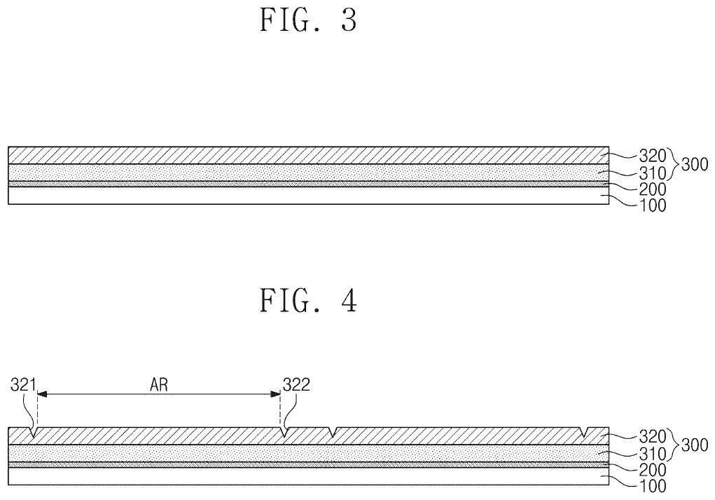

FIGS. 3, 4, 5, 6, 7, 8, 9, and 10 illustrate cross-sectional views showing an example of a method of fabricating a semiconductor package.

Referring to FIG. 3, a carrier substrate 100 may be disposed, and a carrier adhesion layer 200 may be formed on the carrier substrate 100. The carrier substrate 100 may include a worktable, a handling wafer, or a supporting substrate. The carrier substrate 100 may include a rigid material, such as glass, silicon, or metal. The carrier adhesion layer 200 may include a glue that attaches a certain member to the carrier substrate 100.

A first encapsulation layer 300 may be formed on the carrier adhesion layer 200. The formation of the first encapsulation layer 300 may include sequentially forming a first material layer 310 and a second material layer 320 on the carrier adhesion layer 200. The formation of the first material layer 310 may include, for example, coating a polymer material on the carrier adhesion layer 200. The formation of the second material layer 320 may include, for example, attaching a metal foil on the first material layer 310 or depositing a metallic material on the first material layer 310.

Referring to FIG. 4, a first alignment key 321 and a second alignment key 322 may be formed on the second material layer 320. The formation positions of the first alignment key 321 and the second alignment key 322 may define an area AR where semiconductor dies 510, 520, and 530 are disposed.

The first alignment key 321 and the second alignment key 322 may each independently have a depressed shape. The formation of the first alignment key 321 and the second alignment key 322 may include forming a photomask on the second material layer 320 and etching the second material layer 320.

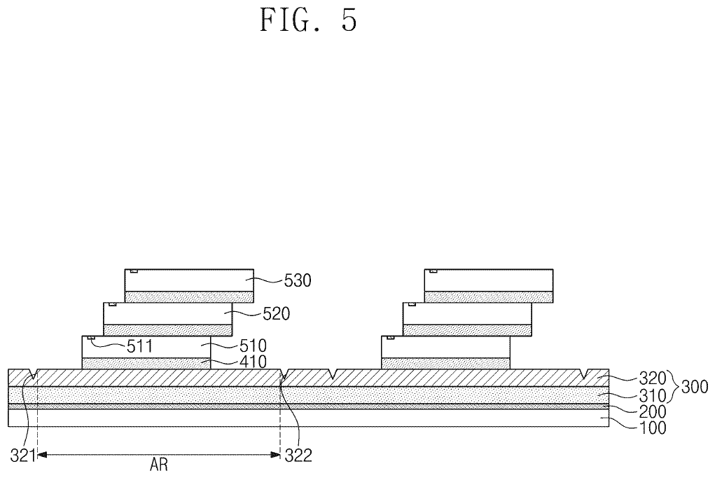

Referring to FIG. 5, a chip stack structure 500, for example, the semiconductor dies 510, 520, and 530 may be offset stacked on the second material layer 320. The chip stack structure 500, for example, the semiconductor dies 510, 520, and 530 may be offset stacked on the area AR that is defined to refer to a region between the first alignment key 321 and the second alignment key 322.

A die adhesion layer 410 may be formed on each of the semiconductor dies 510, 520, and 530. A first semiconductor die 510 may be disposed on the second material layer 320 to allow the die adhesion layer 410 of the first semiconductor die 510 to contact the second material layer 320. Afterwards, a second semiconductor die 520 may be offset stacked on the first semiconductor die 510 to allow the die adhesion layer 410 of the second semiconductor die 520 to contact the first semiconductor die 510. In this step, the second semiconductor die 520 may be offset stacked to expose a contact pad 511 of the first semiconductor die 510. Thereafter, a third semiconductor die 530 may be offset stacked on the second semiconductor die 520 to allow the die adhesion layer 410 of the third semiconductor die 530 to contact the second semiconductor die 520. In this step, the third semiconductor die 530 may be offset stacked to expose a contact pad 511 of the second semiconductor die 520. A direction in which the second semiconductor die 520 is offset stacked on the first semiconductor die 510 may be the same as that in which the third semiconductor die 530 is offset stacked on the second semiconductor die 520.

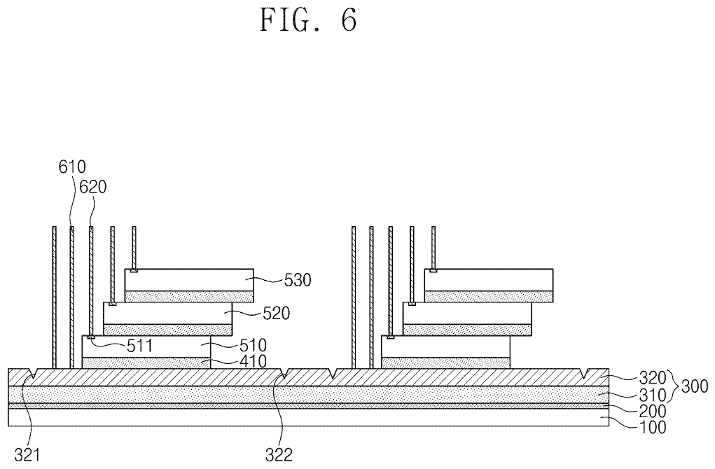

Referring to FIG. 6, first vertical connectors 620 and second vertical connectors 610 may be formed on the second material layer 320. The first vertical connectors 620 and the second vertical connectors 610 may be formed through a wire bonding procedure. The wire bonding procedure may be executed through a wire bonding including a capillary.

The formation of the first vertical connectors 620 may include combining a capillary with the first vertical connectors 620, placing the first vertical connectors 620 on the contact pads 511, descending the capillary to allow the first vertical connectors 620 to attach their end portions to the contact pads 511, ascending the capillary to allow the first vertical connectors 620 to vertically extend from the end portions, and cutting the first vertical connectors 620 to remove the first vertical connectors 620 with which the capillary is combined.

The formation of the second vertical connectors 610 may include combining a capillary with the second vertical connectors 610, placing the second vertical connectors 610 on the second material layer 320 on which the first semiconductor die 510 is not disposed, descending the capillary to allow the second vertical connectors 610 to attach their end portions to the second material layer 320, ascending the capillary to allow the second vertical connectors 610 to vertically extend from the end portions, and cutting the second vertical connectors 610 to remove the second vertical connectors 610 with which the capillary is combined.

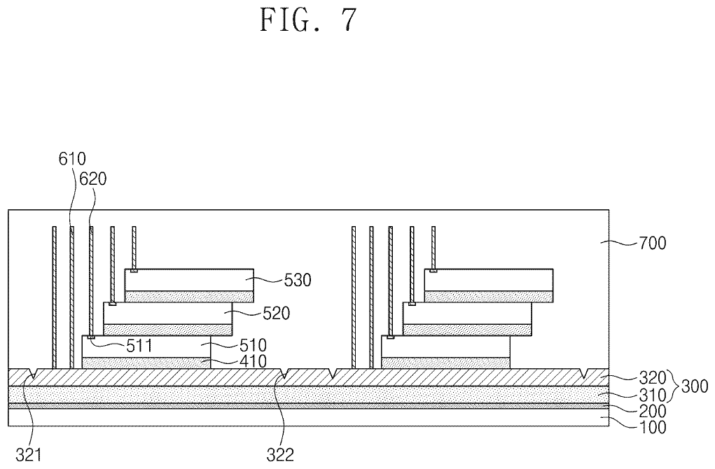

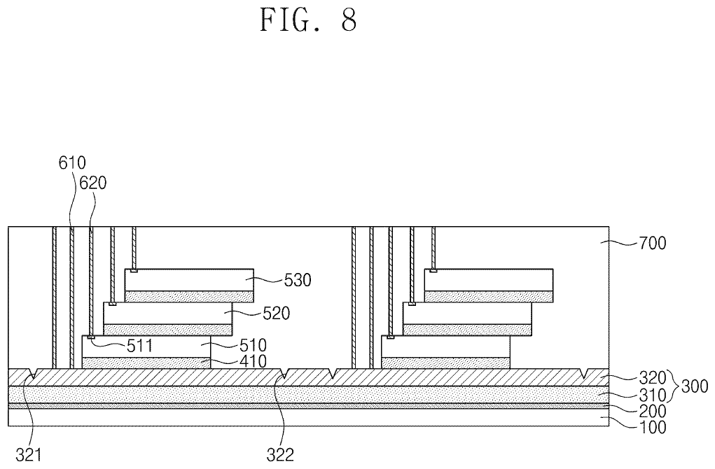

Referring to FIG. 7, a second encapsulation layer 700 may be formed on the second material layer 320. When viewed in vertical section, a height of the second encapsulation layer 700 may be greater than that of the first vertical connectors 620 and that of the second vertical connectors 610.

The second encapsulation layer 700 may be formed in a molding process in which a liquid sealing member. The molding process may include allowing a mold to receive the carrier substrate 100 on which the semiconductor dies 510, 520, and 530 are stacked, introducing the liquid sealing member into the mold, pressing the mold, and curing the introduced sealing member.

Referring to FIG. 8, the first vertical connectors 620 and the second vertical connectors 610 may be exposed.

The first and second vertical connectors 620 and 610 may be exposed through a process for recessing the second encapsulation layer 700. A portion of the second encapsulation layer 700 may be removed such that, when viewed in vertical section, a height of the second encapsulation layer 700 may be the same as that of the first and second vertical connectors 620 and 610. The recess process may include a grinding process.

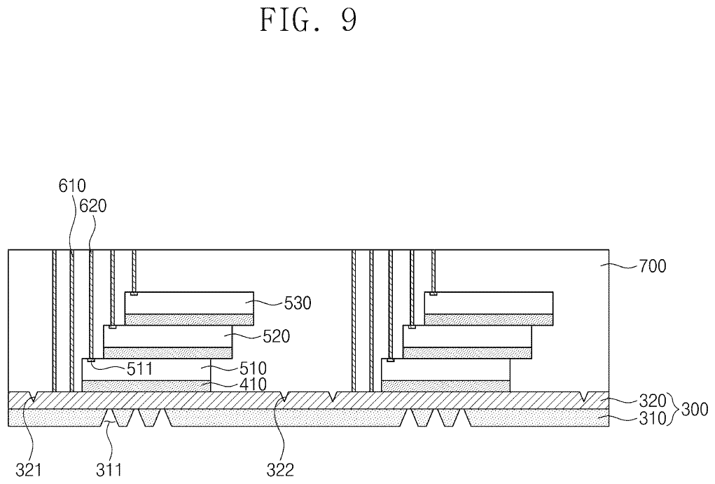

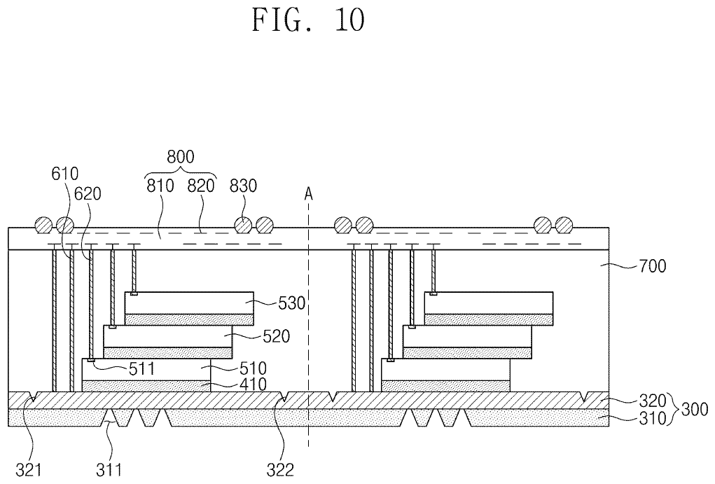

Referring to FIG. 9, a marking pattern 311 may be formed on the first encapsulation layer 300.

The formation of the marking pattern 311 may include removing the carrier substrate 100 and the carrier adhesion layer 200, forming a carrier substrate and a carrier adhesion layer on a surface parallel to another surface that faces the second material layer 320, forming a photomask on the first encapsulation layer 300, etching the first encapsulation layer 300, and removing the carrier substrate and the carrier adhesion layer. A description of the carrier substrate and the carrier adhesion layer may be the same as that of the carrier substrate 100 and the carrier adhesion layer 200. The carrier adhesion layer may be interposed between the carrier substrate and the second encapsulation layer 700.

Referring to FIG. 10, a wiring layer 800 may be formed on the second encapsulation layer 700. A semiconductor package according to some implementations of the present disclosure may undergo a singulation process.

The formation of the wiring layer 800 may include, for example, forming a carrier substrate and a carrier adhesion layer on a surface of the first encapsulation layer 300 parallel to another surface that faces the second encapsulation layer 700, forming a dielectric layer 810 on the second encapsulation layer 700, forming an opening in the dielectric layer 810, forming wiring patterns 820 in the opening, and forming external bonding terminals 830 on the wiring patterns 820.

The singulation process may include forming a protection layer on the dielectric layer 810, removing the carrier substrate and the carrier adhesion layer, and cutting the protection layer, the second encapsulation layer 700, and the first encapsulation layer 300 along a cut line A. A sawing process may be performed to cut the semiconductor package along the cut line A. The sawing process may include a stealth dicing process.

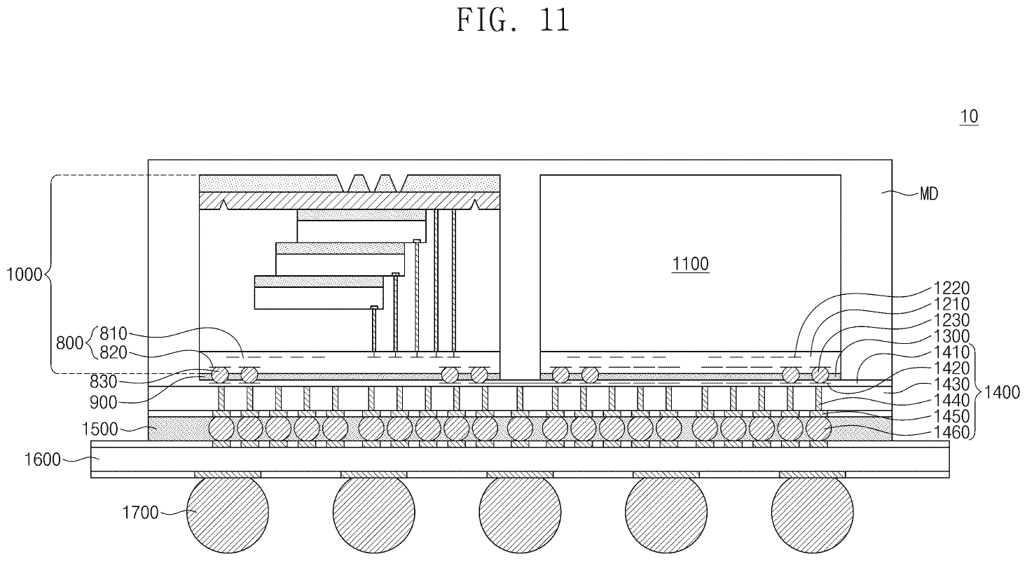

FIG. 11 illustrates a cross-sectional view showing an example of a semiconductor package. Referring to FIG. 11, a semiconductor package 10 may include the semiconductor package 1000 of FIG. 1, and may further include a chip structure 1100, a package substrate 1600, and an interposer substrate 1400.

The interposer substrate 1400 may be provided on the package substrate 1600. The interposer substrate 1400 may include a base substrate 1430, a plurality of through electrodes 1440 that penetrate the base substrate 1430, and wiring patterns 1420 on the base substrate 1430. The interposer substrate 1400 may further include external bonding members 1460 and wiring patterns 1450 on the base substrate 1430. The wiring patterns 1420 may be provided in a dielectric layer 1410.

The semiconductor package 1000 according to the present disclosure may be connected through the external bonding terminals 830 to the interposer substrate 1400. The chip structure 1100 may include a semiconductor package or a semiconductor chip. The chip structure 1100 may be an application specific integrated circuit (ASIC) or a system-on-chip (SOC). The chip structure 1100 may be called a host or an application processor (AP). The chip structure 1100 may be connected through external bonding terminals 1230 to the interposer substrate 1400.

A mold layer MD may cover a top surface of the interposer substrate 1400, the chip structure 1100, and the semiconductor package 1000 according to the present disclosure. The mold layer MD may include a dielectric resin, such as an epoxy molding compound (EMC). The mold layer MD may further include fillers, and the fillers may be dispersed in the dielectric resin. The fillers may include, for example, silicon oxide (SiO2).

The interposer substrate 1400 may be bonded through the external bonding members 1460 to the package substrate 1600. External bonding members 1700 may be bonded to a lower end of the package substrate 1600. The external bonding members 1460 and 1700 may include at least one selected from copper bumps, copper pillars, and solder balls.

An underfill 900 may be provided between the interposer substrate 1400 and the semiconductor package 1000 according to the present disclosure and between the chip structure 1100 and the interposer substrate 1400. An underfill 1500 may be provided between the interposer substrate 1400 and the package substrate 1600. The underfills 900 and 1500 may be formed by dispensing and curing processes. The underfills 900 and 1500 may include an epoxy resin, and may protect the external bonding members 1460 and 1700.

A semiconductor package according to the present disclosure may include an encapsulation layer, and the encapsulation layer may include a metal layer. The presence of the metal layer may improve visibility of a marking pattern. In addition, not a wafer-level alignment key but a chip-level alignment key may be disposed to increase accuracy of alignment. A metal layer and a wiring layer may be connected through a vertical connector, and heat generated from a semiconductor chip may be outwardly discharged through the metal layer and a metal wire. Accordingly, the semiconductor package may improve in thermal radiation efficiency.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the present disclosure has been described in connection with some implementations illustrated in the accompanying drawings, it will be understood by one of ordinary skill in the art that variations in form and detail may be made therein without departing from the spirit and essential feature of the present disclosure. The above disclosed implementations should thus be considered illustrative and not restrictive.

What is claimed is:

1. A semiconductor package, comprising:
a first encapsulation layer;
a plurality of semiconductor dies stacked in a staircase structure on the first encapsulation layer;
a second encapsulation layer that covers the plurality of semiconductor dies and the first encapsulation layer;
a wiring layer on the second encapsulation layer; and
a plurality of first vertical connectors that connect the plurality of semiconductor dies with the wiring layer,
wherein the first encapsulation layer includes:
a polymer layer; and
a metal layer between the polymer layer and the second encapsulation layer.

2. The semiconductor package of claim 1, wherein
the metal layer includes at least one of copper, aluminum, tungsten, or titanium, and
the polymer layer includes at least one of polypropylene, polyimide, polyvinyl alcohol, or polyvinylidene fluoride.

3. The semiconductor package of claim 1, wherein
a thickness of the polymer layer is in a range of 10 nm to 10 μm, and
a thickness of the metal layer is in a range of 50 nm to 50 μm.

4. The semiconductor package of claim 1, wherein a thickness of the polymer layer is less than a thickness of the metal layer.

5. The semiconductor package of claim 1, wherein the first encapsulation layer includes a marking pattern on a first surface parallel to a second surface that faces the second encapsulation layer, and
wherein the marking pattern includes at least one opening.

6. The semiconductor package of claim 5, wherein the at least one opening extends through the polymer layer.

7. The semiconductor package of claim 6, wherein a depth of the at least one opening is greater than a thickness of the polymer layer.

8. The semiconductor package of claim 5, wherein a depth of the at least one opening is less than a thickness of the polymer layer.

9. The semiconductor package of claim 1, comprising a plurality of second vertical connectors that connect the metal layer with the wiring layer.

10. The semiconductor package of claim 1, wherein the metal layer includes a first alignment key and a second alignment key on a surface that faces the second encapsulation layer,
wherein the first alignment key and the second alignment key are horizontally spaced apart from each other,
wherein the first alignment key and the second alignment key have a depressed shape, and
wherein the second encapsulation layer is disposed on the first alignment key and the second alignment key.

11. The semiconductor package of claim 10, wherein the plurality of semiconductor dies are horizontally disposed between the first alignment key and the second alignment key.

12. The semiconductor package of claim 10, comprising a plurality of second vertical connectors that connect the metal layer with the wiring layer,
wherein the plurality of second vertical connectors are horizontally disposed between the first alignment key and the second alignment key.

13. The semiconductor package of claim 10, wherein the first encapsulation layer includes a marking pattern on a first surface parallel to a second surface that faces the second encapsulation layer,
wherein the marking pattern includes at least one opening, and
wherein the marking pattern is horizontally disposed between the first alignment key and the second alignment key.

14. A semiconductor package, comprising:
a metal layer;
a plurality of semiconductor dies stacked in a staircase structure on the metal layer;
a second encapsulation layer that covers the plurality of semiconductor dies and the metal layer;
a wiring layer on the second encapsulation layer;
a plurality of first vertical connectors that connect the plurality of semiconductor dies with the wiring layer; and
a plurality of second vertical connectors that connect the metal layer with the wiring layer,
wherein the plurality of second vertical connectors are horizontally spaced apart from the plurality of semiconductor dies.

15. The semiconductor package of claim 14, wherein a length of the plurality of second vertical connectors is greater than a length of the plurality of first vertical connectors.

16. The semiconductor package of claim 14, wherein the plurality of second vertical connectors include at least one of copper, aluminum, tungsten, or titanium.

17. The semiconductor package of claim 14, wherein a material of the plurality of second vertical connectors is the same as a material of the metal layer.

18. A semiconductor package, comprising:
a metal layer;
a first semiconductor die stacked in a staircase structure on the metal layer;
a second encapsulation layer that covers the first semiconductor die and the metal layer;
a wiring layer on the second encapsulation layer; and
a plurality of first vertical connectors that connect the first semiconductor die with the wiring layer,
wherein the metal layer includes a first alignment key on a surface that faces the second encapsulation layer,
wherein the first alignment key has a depressed shape, and
wherein the second encapsulation layer fills the first alignment key.

19. The semiconductor package of claim 18, wherein the metal layer includes a second alignment key on the surface that faces the second encapsulation layer, the second alignment key being horizontally spaced apart from the first alignment key,
wherein the second alignment key has a depressed shape,
wherein the second encapsulation layer fills the second alignment key, and
wherein the first semiconductor die is between the first alignment key and the second alignment key.

20. The semiconductor package of claim 18, comprising a plurality of second vertical connectors that connect the metal layer with the wiring layer,
wherein the metal layer includes a second alignment key on the surface that faces the second encapsulation layer, the second alignment key being horizontally spaced apart from the first alignment key,
wherein the second alignment key has a depressed shape,
wherein the second encapsulation layer fills the second alignment key, and
wherein the plurality of second vertical connectors are horizontally disposed between the first alignment key and the second alignment key.
